(19) United States
(12) Patent Application Publication
(10) Pub. No.: US 2025/0351416 A1
(43) Pub. Date: Nov. 13, 2025

(54) SEMICONDUCTOR DEVICES

(71) Applicant: SAMSUNG ELECTRONICS CO., LTD., Suwon-si (KR)

(72) Inventors: Sungsoo KIM, Suwon-shi (KR); Minchul AHN, Suwon-si (KR); Sanghyun PARK, Suwon-si (KR); Jongmin BAEK, Suwon-si (KR); Junchae LEE, Suwon-si (KR); Kangsub YIM, Suwon-si (KR)

(73) Assignee: SAMSUNG ELECTRONICS CO., LTD., Suwon-si (KR)

(21) Appl. No.: 18/979,986

(22) Filed: Dec. 13, 2024

(30) Foreign Application Priority Data
May 10, 2024 (KR) 10-2024-0061757

(51) Int. Cl. H10D 30/00; H10D 30/01

(52) U.S. Cl. CPC H10D 30/502; H10D 30/0191

(57) ABSTRACT

A semiconductor device includes: an active region on a substrate; a gate structure intersecting the active region and including a gate electrode; a source/drain region on the active region; a first contact structure on and connected to the source/drain region; first and second insulating layers on the gate and first contact structures; a second contact structure connected to the gate electrode and including: a first contact via in the first insulating layer; and a first conductive cap layer in the second insulating layer and on the first contact via; a via structure connected to the first contact structure, the via structure including: a second contact via in the first insulating layer; and a second conductive cap layer in the second insulating layer and on the second contact via; and interconnection lines on the second insulating layer connected to the second contact structure and the via structure.

### CROSS-REFERENCE TO RELATED APPLICATIONS

This application is based on and claims priority to Korean Patent Application No. 10-2024-0061757, filed on May 10, 2024 in the Korean Intellectual Property Office, the disclosure of which is incorporated herein by reference in its entirety.

### BACKGROUND

### 1. Field

The present disclosure relates to semiconductor devices.

### 2. Description of Related Art

As demand for high performance, high speed, and/or multifunctional semiconductor devices increases, the degree of integration of semiconductor devices has increased. In manufacturing fine-patterned semiconductor devices in response to the trend for high integration in semiconductor devices, it is necessary to implement patterns having a fine width or a fine separation distance.

### SUMMARY

Provided are semiconductor devices including a contact structure having a plurality of connection structures respectively having different horizontal widths in order to prevent a short-circuit phenomenon between a contact structure and an interconnection line.

Further provided is a semiconductor device including a gate contact structure and/or a source/drain contact structure that may include a contact via and a conductive cap layer disposed on the contact via and having a horizontal width smaller than that of the contact via. Accordingly, the present disclosure may provide a semiconductor device in which a short-circuit phenomenon between the gate contact structure and the interconnection line and between the source/drain contact structure and the interconnection line is minimized or prevented.

According to an aspect of the disclosure, a semiconductor device includes: an active region on a substrate; a gate structure including a gate electrode, wherein the gate structure intersects the active region; a source/drain region on the active region, wherein the source/drain region is on at least one side of the gate structure; a first contact structure on the source/drain region and connected to the source/drain region; a first insulating layer and a second insulating layer sequentially disposed on the gate structure and the first contact structure; a second contact structure connected to the gate electrode, wherein the second contact structure includes: a first contact via in the first insulating layer and protruding vertically from an upper surface of the gate electrode; and a first conductive cap layer in the second insulating layer and on the first contact via; a via structure connected to the first contact structure, wherein the via structure includes: a second contact via in the first insulating layer and protruding vertically from an upper surface of the first contact structure; and a second conductive cap layer in the second insulating layer and on the second contact via; and a plurality of interconnection lines on the second insulating layer, wherein the plurality of interconnection lines are each connected to the second contact structure and the via structure.

According to an aspect of the disclosure, a semiconductor device includes: an active region on a substrate; a gate structure including a gate electrode, wherein the gate structure intersects the active region; a source/drain region on the active region, wherein the source/drain region is on at least one side of the gate structure; a contact structure on the source/drain region and connected to the source/drain region; a first insulating layer and a second insulating layer sequentially disposed on the gate structure and the contact structure; a via structure connected to the contact structure, the via structure including a contact via in the first insulating layer and vertically protruding from an upper surface of the contact structure, and a conductive cap layer in the second insulating layer and on the contact via; and an etch stop layer on the second insulating layer and the via structure, wherein a maximum horizontal width of the conductive cap layer is smaller than a maximum horizontal width of the contact via, and a side surface of the conductive cap layer and a side surface of the contact via form a first surface including a step portion between the side surface of the conductive cap layer and the side surface of the contact via.

According to an aspect of the disclosure, a semiconductor device includes: an active region extending on a substrate in a first direction; a gate structure including a gate electrode, wherein the gate structure intersects the active region and extends in a second direction; a source/drain region on the active region, wherein the source/drain region is on at least one side of the gate structure; a first contact structure on the source/drain region and connected to the source/drain region, wherein an upper surface of the first contact structure and an upper surface of the gate structure are on the same level; a second contact structure connected to the gate electrode, wherein the second contact structure includes a first contact via on the gate electrode and a first conductive cap layer on the first contact via, and wherein the first contact via has a first thickness and the first conductive cap layer has a second thickness; a via structure connected to the first contact structure, wherein the via structure includes a second contact via on the first contact structure and a second conductive cap layer on the second contact via, and wherein the second contact via has a thickness equal to the first thickness and the second conductive cap layer has a thickness equal to the second thickness; an insulating layer surrounding a side surface of the second contact structure and a side surface of the via structure and the first contact structure; and a plurality of interconnection lines on the insulating layer, wherein the plurality of interconnection lines are each connected to the second contact structure and the via structure.

The disclosure is not limited to the foregoing content and may be more easily understood through the description of one or more embodiments of the present disclosure provided below.

### BRIEF DESCRIPTION OF DRAWINGS

The above and other aspects and features of certain embodiments of the present disclosure will be more clearly understood from the following detailed description, taken in conjunction with the accompanying drawings, in which:

FIG. 1 is a plan view of a semiconductor device according to an one or more embodiments of the present disclosure;

FIG. 2 is a cross-sectional view illustrating a semiconductor device according to one or more embodiments of the present disclosure;

FIG. 3 is a cross-sectional view illustrating a semiconductor device according to one or more embodiments of the present disclosure;

FIGS. 4A and 4B are partially enlarged views of a semiconductor device according to one or more embodiments of the present disclosure;

FIGS. 5A and 5B are partially enlarged views of a semiconductor device according to one or more embodiments of the present disclosure;

FIGS. 6A and 6B are partially enlarged views of a semiconductor device according to one or more embodiments of the present disclosure;

FIG. 7 is a cross-sectional view illustrating a semiconductor device according to one or more embodiments of the present disclosure; and

FIGS. 8, 9, 10, 11, 12, 13, 14, 15, 16 and 17 are vertical cross-sectional views illustrating a method of manufacturing a semiconductor device according to an one or more embodiments of the present disclosure.

### DETAILED DESCRIPTION

Hereinafter, one or more embodiments of the present disclosure will be described with reference to the accompanying drawings.

One or more embodiments of the present disclosure may be modified into various different forms or various example embodiments may be combined therewith, and the range of the present disclosure is not limited to the example embodiments described below. Additionally, the one or more embodiments of the present disclosure are provided to more completely explain the present disclosure for those skilled in the art. Accordingly, the shapes and dimensions of elements in the drawings may be exaggerated for clearer explanation, and elements indicated by the same symbol in the drawings are the same elements.

The terms used herein are for the purpose of describing particular embodiments only and are not intended to limit the present disclosure. The singular also includes the plural unless specifically stated otherwise in the phrase. It will be further understood that the terms “comprises,” “comprising,” “includes,” “including,” “has” and/or “having” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Although numerical terms (e.g., “first” and “second”) are used herein to describe various members, parts, regions, layers and/or sections, these members, parts, regions, layers and/or sections are not to be limited by these terms. These terms are only used to distinguish one member, part, region, layer or section from another member, part, region, layer or section. Thus, for example, a first member, part, region, layer or section discussed below could be termed a second, part, region, layer or section without departing from the teachings of the illustrated embodiments.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

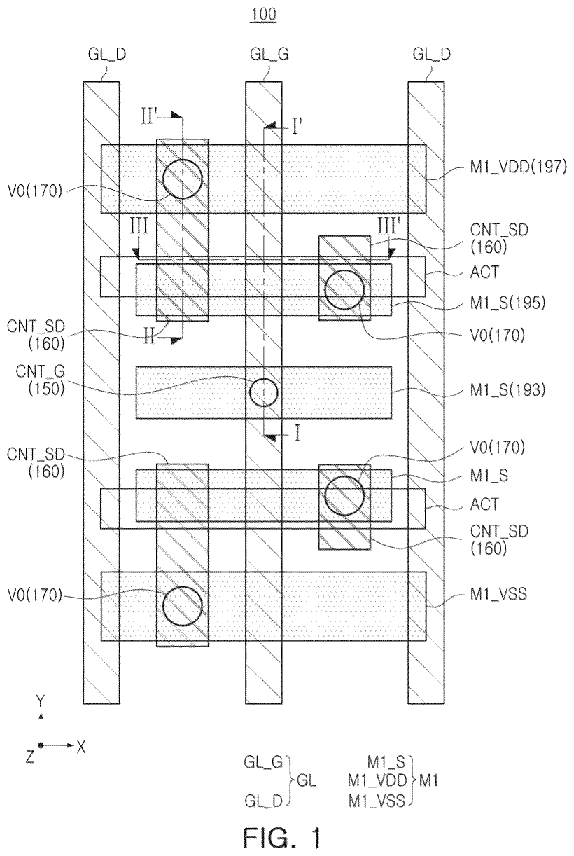

FIG. 1 is a plan view of a semiconductor device according to one or more embodiments. FIG. 1 may be a plan view illustrating a region corresponding to a standard cell among cells included in a semiconductor device.

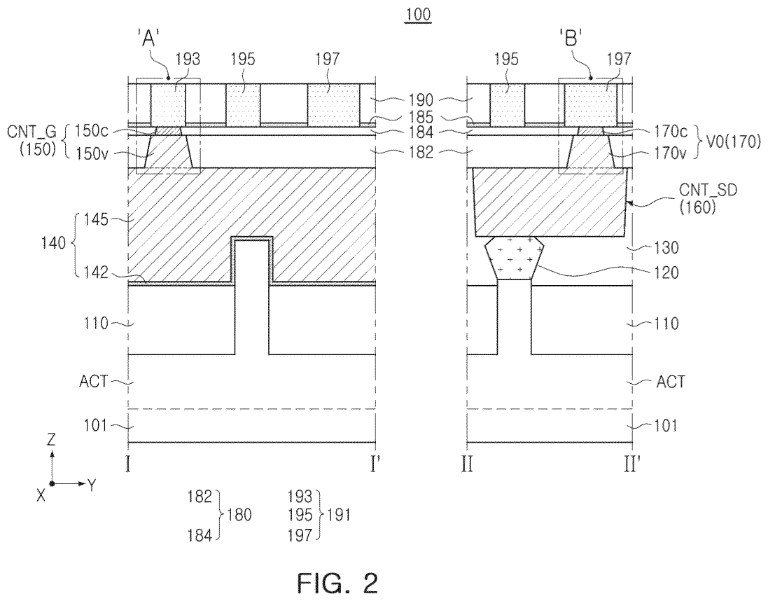

FIG. 2 is a cross-sectional view illustrating a semiconductor device according to one or more embodiments. FIG. 2 illustrates cross-sections taken along cutting lines I-I′ and II-II′ of the semiconductor device of FIG. 1.

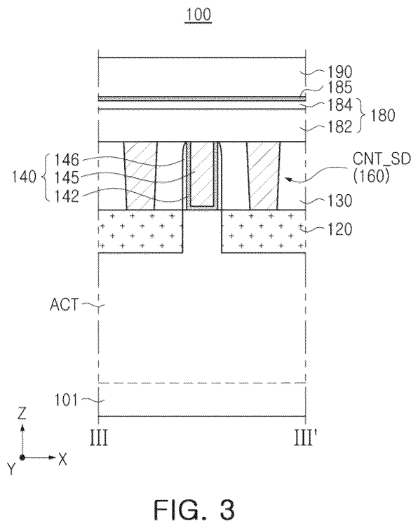

FIG. 3 is a cross-sectional view illustrating a semiconductor device according to one or more embodiments. FIG. 3 illustrates cross-sections taken along cutting line III-III′ of the semiconductor device of FIG. 1.

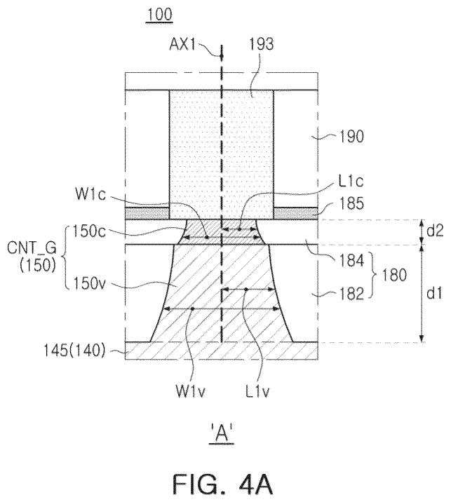

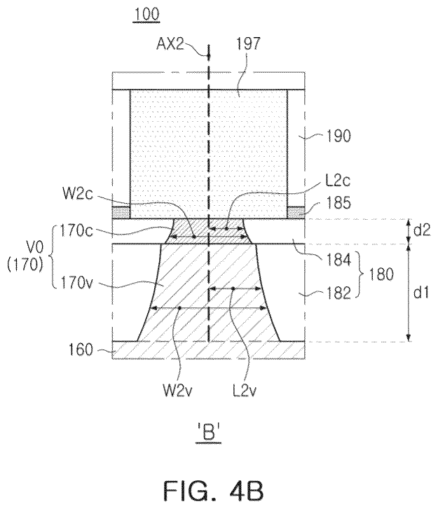

FIGS. 4A and 4B are partially enlarged views of a semiconductor device according to one or more embodiments. FIG. 4A is a partially enlarged view of region ‘A’ in FIG. 2, and FIG. 4b is a partially enlarged view of region ‘B’ of FIG. 2.

For convenience of explanation, only major components of the semiconductor device are illustrated in FIGS. 1 to 4B.

Referring to FIGS. 1 to 4B, a semiconductor device 100 may include a substrate 101, an active region ACT extending in a first direction (e.g. X-direction) and gate lines GL extending in a second direction (e.g., Y-direction). A gate contact structure CNT_G may be connected to the gate lines GL, source/drain contact structures CNT_SD may be connected to the active regions ACT, via structures V0 may be connected to the source/drain contact structures CNT_SD, and interconnection lines M1 may be connected to the via structures V0. The semiconductor device 100 may further include device isolating layers 110, a lower interlayer insulating layer 130, an intermediate interlayer insulating layer 180, an etch stop layer 185, and an upper interlayer insulating layer 190. According to one or more embodiments, the semiconductor device 100 may further include interconnection lines disposed in an upper portion of the interconnection lines M1 and electrically connecting the interconnection lines M1.

The substrate 101 may have an upper surface extending in the X-direction and the Y-direction. The substrate 101 may include a semiconductor material, such as a group IV semiconductor, a group III-V compound semiconductor, or a group II-VI oxide semiconductor. For example, examples of the group IV semiconductor may include silicon, germanium, or silicon-germanium. The substrate 101 may be provided as a bulk wafer, an epitaxial layer, an epitaxial layer, a silicon on insulator (SOI) layer, or a semiconductor on insulator (SeOI) layer.

The device isolating layers 110 may define active fins in the substrate 101. The device isolating layers 110 may be formed of an insulating material. The device isolating layers 110 may be formed by, for example, a shallow trench isolation (STI) process. The device isolating layers 110 may be, for example, an oxide, a nitride, or combinations thereof.

The active regions ACT may be defined by the device isolating layers 110 in the substrate 101 and may include one or more active fins extending in a first direction, for example, the X-direction. The active fins may have an active fin structure protruding from the substrate 101. The active fins may be configured as a portion of the substrate 101 or may include an epitaxial layer grown from the substrate 101. However, on a side surface of a gate structure 140, the active fins on the substrate 101 may be recessed and source/drain regions 120 may be disposed.

The source/drain regions 120 may be disposed on both sides of the gate structure 140 and on the active region ACT. The source/drain regions 120 may serve as a source region or a drain region of the semiconductor device 100. According to one or more embodiments, the source/drain regions 120 may have an elevated source/drain shape in which an upper surface thereof is disposed to be higher than a lower surface of the gate structure 140, but the present disclosure is not limited thereto. For example, the upper surface of the source/drain regions 120 may be disposed to be lower than the lower surface of the gate structure 140. In one or more embodiments, the source/drain regions 120 are illustrated as pentagonal shapes, but the source/drain regions 120 may have various shapes, and may have, for example, the shape of polygons, circles and rectangles. Additionally, in one or more embodiments, the source/drain regions 120 are illustrated as having a structure disposed on one active fin, but the present disclosure is not limited thereto. For example, the source/drain regions 120 may have a structure in which the source/drain regions 120 are connected to each other or merged on multiple active fins. The source/drain regions 120 may include, for example, silicon or silicon germanium (SiGe).

The gate lines GL extend in a second direction, for example, the Y-direction, and may be spaced apart from each other in the first direction, for example, the X-direction (see, e.g., FIG. 1). The gate lines GL may include gate electrodes GL_G and dummy gate electrodes GL_D configured to provide semiconductor components. For example, the gate lines GL_G disposed on edges (or boundaries) of the standard cell region may be dummy gate electrodes GL_D.

The gate structures 140 may be disposed to intersect the active fins in an upper portion of the active region ACT and extend in a second direction, for example, the Y-direction (see, e.g., FIG. 2). The gate structures 140 may be disposed to correspond to the gate electrodes GL_G of FIG. 1. The gate structure 140 may include a gate dielectric layer 142, a gate electrode layer 145, and gate spacer layers 146.

The gate dielectric layer 142 may be disposed between the active region ACT and the gate electrode layer 145. The gate dielectric layer 142 may include an oxide, a nitride, or a high-κ material. The expression “high-κ material” may refer to a dielectric material having a dielectric constant higher than that of a silicon oxide film (SiO₂).

The gate electrode layer 145 may be disposed on the gate dielectric layer 142. The gate electrode layer 145 may include a conductive material, for example, a metal nitride such as titanium nitride (TiN), tantalum nitride (TaN), or tungsten nitride (WN), a metal material such as aluminum (Al), tungsten (W), or molybdenum (Mo), or a semiconductor material such as doped polysilicon. The gate electrode layer 145 may be formed of two or more multiple layers.

The gate spacer layers 146 may be disposed on both sides of the gate electrode layer 145. The gate spacer layers 146 may insulate the source/drain regions 120 and the gate electrode layer 145 from each other. The gate spacer layers 146 may have a multilayer structure according to one or more embodiments. The gate spacer layers 146 may be formed of an oxide, a nitride, or an oxynitride, and may be formed of, specifically, a low-κ film. For example, the gate spacer layers 146 may include at least one of SiO, SiN, SiCN, SiOC, SION, and SiOCN.

The lower interlayer insulating layer 130 may cover the source/drain regions 120 on at least one side of the gate structure 140. The lower interlayer insulating layer 130 may include, for example, at least one of an oxide, a nitride, or an oxynitride, and may include a low-κ material.

The source/drain contact structures CNT_SD may be disposed in the lower interlayer insulating layer 130 and connected to the source/drain regions 120, and may apply an electrical signal to the source/drain regions 120. The source/drain contact structures CNT_SD may be disposed to recess the source/drain regions 120 by a predetermined depth, but the present disclosure not limited thereto. The source/drain contact structures CNT_SD may be a conductive material, for example, a metal nitride such as titanium nitride (TiN), tantalum nitride (TaN), or tungsten nitride (WN), a metallic material such as aluminum (Al), tungsten (W), or molybdenum (Mo), or a semiconductor material such as doped polysilicon. According to one or more embodiments, the source/drain contact structures CNT_SD may include the same conductive material as the gate structures 140. According to one or more embodiments, the source/drain contact structures CNT_SD may further include a barrier metal layer disposed along an outer surface thereof. Additionally, according to one or more embodiments, the source/drain contact structures CNT_SD may further include a metal-semiconductor layer, such as a silicide layer, disposed in an interface in contact with the source/drain regions 120. The source/drain contact structures CNT_SD may also be referred to as source/drain contact structures 160.

The gate structures 140 and the source/drain contact structures CNT_SD may be on substantially the same level as each other. For example, upper surfaces of the gate structures 140 and upper surfaces of the source/drain contact structures CNT_SD may be at the same distance from an upper surface of the substrate 101.

Horizontal widths of the source/drain contact structures CNT_SD may decrease toward a lower region. For example, the horizontal widths of the source/drain contact structures CNT_SD may decrease as the source/drain contact structures CNT_SD approach the upper surface of the substrate 101 or the source/drain region 120.

The intermediate interlayer insulating layers 180 may include a first intermediate interlayer insulating layer 182 on the gate structure 140, the source/drain contact structures CNT_SD, and the lower interlayer insulating layer 130, and a second intermediate interlayer insulating layer 184 on the first intermediate interlayer insulating layer 182. The first intermediate interlayer insulating layer 182 may be formed of an oxide, a nitride, or an oxynitride. The first intermediate interlayer insulating layer 182 may include, for example, at least one of SiO, SiN, and SiON. In one or more embodiments, the first intermediate interlayer insulating layer 182 may be formed of SiN. The second intermediate interlayer insulating layer 184 may be formed of an oxide, a nitride, or an oxynitride, and specifically, may be formed of a low-κ film. The second intermediate interlayer insulating layer 184 may include, for example, at least one of SiO, SiN, SiCN, SiOC, SiON, and SiOCN. In this embodiment, the second intermediate interlayer insulating layer 184 may be formed of SiN and/or a low-κ film.

Referring to FIG. 4A, the gate contact structures CNT_G may include a first contact via 150v on the gate structure 140 and a first conductive cap layer 150c on the first contact via 150v. The gate contact structures CNT_G may also be referred to as gate contact structures 150.

The first contact via 150v may protrude vertically from an upper surface of the gate electrode layer 145 and may be disposed in the first intermediate interlayer insulating layer 182.

A horizontal width W1v of the first contact via 150v may decrease in a direction moving away from an upper surface of the gate electrode layer 145 toward an upper region. Put another way, the horizontal width W1v of the first contact via 150v may gradually increase in a direction moving toward a lower region of the first contact via 150v (i.e., toward the upper surface of the gate electrode layer 145). A side surface of the first contact via 150v may have a curved shape. Specifically, the side surface of the first contact via 150v may have a concave (or curved) shape toward a central axis AX1 of the first contact via 150v. More specifically, the side surface of the first contact via 150v may have a curved shape so that a horizontal distance L1v between the side surface of the first contact via 150v and the central axis AX1 of the first contact via 150v increases in a direction toward the lower region of the first contact via 150v (i.e., toward the upper surface of the gate electrode layer 145).

Accordingly, the first intermediate interlayer insulating layer 182 may have a curved side surface in a portion in contact with the side surface of the first contact via 150v. Specifically, a side surface of the first intermediate interlayer insulating layer 182 may have a convex shape toward the central axis AX1 of the first contact via 150v. More specifically, the side surface of the first intermediate interlayer insulating layer 182 may have a curved shape so that the horizontal distance L1v between the side surface of the first intermediate interlayer insulating layer 182 and the central axis AX1 of the first contact via 150v decreases toward the upper region.

In one or more embodiments, a vertical thickness d1 of the first contact via 150v may range from about 10 nm to about 30 nm. In one or more embodiments, the vertical thickness d1 of the first contact via 150v may range from about 10 nm to about 20 nm. In one or more embodiments, the vertical thickness d1 of the first contact via 150v may range from about 10 nm to about 15 nm.

The first contact via 150v and the gate electrode layer 145 may be integrated with each other. Put another way, a boundary surface between the first contact via 150v and the gate electrode layer 145 may not be distinguished from each other. Put another way, the first contact via 150v may include the same conductive material as the gate electrode layer 145.

The first conductive cap layer 150c may be disposed on the first contact via 150v in the second intermediate interlayer insulating layer 184.

A horizontal width W1c of the first conductive cap layer 150c may decrease from an upper surface of the first contact via 150v to the upper region. Put another way, the horizontal width W1c of the first conductive cap layer 150c may gradually increase toward a lower region of the first conductive cap layer 150c. A side surface of the first conductive cap layer 150c may have a curved shape. Specifically, the first conductive cap layer 150c may have a concave (or curved) shape toward a central axis AX1. Here, the central axis AX1 of the first conductive cap layer 150c may correspond to the central axis AX1 of the first contact via 150v. More specifically, the side surface of the first conductive cap layer 150c may have a curved shape so that a horizontal distance L1c between the side surface of the first conductive cap layer 150c and the central axis AX1 of the first conductive cap layer 150c increases toward the lower region.

The horizontal width W1c of the first conductive cap layer 150c may be smaller than the horizontal width W1v of the first contact via 150v. For example, a maximum horizontal width W1c of the first conductive cap layer 150c may be smaller than a minimum horizontal width W1v of the first contact via 150v.

Accordingly, the second intermediate interlayer insulating layer 184 may have a curved side surface in a portion in contact with the side surface of the first conductive cap layer 150c. Specifically, a side surface of the second intermediate interlayer insulating layer 184 may have a convex shape toward the central axis AX1 of the first conductive cap layer 150c. More specifically, the side surface of the second intermediate interlayer insulating layer 184 may have a curved shape so that a horizontal distance L1v between the side surface of the second intermediate interlayer insulating layer 184 and the central axis AX1 of the first conductive cap layer 150c may decrease towards the upper region. Put another way, the second intermediate interlayer insulating layer 184 may have an overhang structure.

In one or more embodiments, a vertical thickness d2 of the first conductive cap layer 150c may range from about 3 nm to about 10 nm. In one or more embodiments, the vertical thickness d2 of the first conductive cap layer 150c may range from about 3 nm to about 8 nm.

The first conductive cap layer 150c may include a conductive material, and may include, for example, a metal nitride such as titanium nitride (TiN), tantalum nitride (TaN), or tungsten nitride (WN), and/or a metallic material such as aluminum (Al), tungsten (W), or molybdenum (Mo) or a semiconductor material such as doped polysilicon. In one or more embodiments, the first conductive cap layer 150c may include molybdenum (Mo), but the present disclosure is not limited thereto.

The first contact via 150v may have a step portion with the first conductive cap layer 150c. Put another way, the side surface of the first contact via 150v and the side surface of the first conductive cap layer 150c may have a step portion. Accordingly, at least a portion of an upper surface of the first conductive cap layer 150c may be in contact with the second intermediate interlayer insulating layer 184. Put another way, at least a portion of the second intermediate interlayer insulating layer 184 may overlap the upper surface of the first conductive cap layer 150c.

Referring to FIG. 4B, the via structure V0 may include a second contact via 170v on the source/drain contact structure 160 and a second conductive cap layer 170c on the second contact via 170v. The via structure V0 may also be referred to as the via structure 170.

The second contact via 170v has a shape similar to that of the first contact via 150v described with reference to FIG. 4A, and the second conductive cap layer 170c may have a shape similar to that of the first conductive cap layer 150c described with reference to FIG. 4A.

The second contact via 170v may protrude vertically from an upper surface of the source/drain contact structure 160, and may be disposed in the first intermediate interlayer insulating layer 182.

A horizontal width W2v of the second contact via 170v may decrease from the upper surface of the source/drain contact structure 160 to the upper region. Put another way, the horizontal width W2v of the second contact via 170v may gradually increase toward the lower region of the second contact via 170v. A side surface of the second contact via 170v may have a curved shape. Specifically, the side of the second contact via 170v may have a concave (or curved) shape toward a central axis AX2 of the second contact via 170v. More specifically, the side surface of the second contact via 170v may have a curved shape so that a horizontal distance L2v between the side surface of the second contact via 170v and the central axis AX2 of the second contact via 170v increases toward the lower region.

The first intermediate interlayer insulating layer 182 may have a curved side surface in a portion in contact with the side surface of the second contact via 170v. Specifically, the side surface of the first intermediate interlayer insulating layer 182 may have a convex shape toward the central axis AX2 of the second contact via 170v. More specifically, the side surface of the first intermediate interlayer insulating layer 182 may have a curved shape so that the horizontal distance L2v between the side surface of the first intermediate interlayer insulating layer 182 and the central axis AX2 of the second contact via 170v decreases toward the upper region.

In one or more embodiments, a vertical thickness d1 of the second contact via 170v may be substantially the same as the vertical thickness d1 of the first contact via 150v described with reference to FIG. 4A.

The second contact via 170v and the source/drain contact structure 160 may be integrated with each other. Put another way, a boundary surface between the second contact via 170v and the source/drain contact structure 160 may not be distinguished from each other. Put another way, the second contact via 170v may include the same conductive material as the source/drain contact structure 160.

The second conductive cap layer 170c may be disposed on the second contact via 170v in the second intermediate interlayer insulating layer 184.

A horizontal width W2c of the second conductive cap layer 170c may decrease in a direction from an upper surface of the second contact via 170v to the upper region. Put another way, the horizontal width W2c of the second conductive cap layer 170c may gradually increase toward a lower region of the second conductive cap layer 170c. A side surface of the second conductive cap layer 170c may have a curved shape. Specifically, the second conductive cap layer 170c may have a concave (or curved) shape toward a central axis AX2. Here, the central axis AX2 of the second conductive cap layer 170c may correspond to the central axis AX2 of the second contact via 170v. More specifically, the side surface of the second conductive cap layer 170c may have a curved shape so that a horizontal distance L2c between the side surface of the second conductive cap layer 170c and the central axis AX2 of the second conductive cap layer 170c increases in a direction toward the lower region.

The horizontal width W2c of the second conductive cap layer 170c may be smaller than the horizontal width W2v of the second contact via 170v. For example, a maximum value of the horizontal width W2c of the second conductive cap layer 170c may be smaller than a minimum value of the horizontal width W2v of the second contact via 170v.

The second intermediate interlayer insulating layer 184 may have a curved side sur face in a portion in contact with the side surface of the second conductive cap layer 170c. Specifically, a side of the second intermediate interlayer insulating layer 184 may have a convex shape toward the central axis AX2 of the second conductive cap layer 170c. More specifically, the side surface of the second intermediate interlayer insulating layer 184 may have a curved shape so that the horizontal distance L2v between the side surface of the second intermediate interlayer insulating layer 184 and the central axis AX2 of the second conductive cap layer 170c decreases toward the upper region. Put another way, the second intermediate interlayer insulating layer 184 may have an overhang structure.

In one or more embodiments, a vertical thickness d2 of the second conductive cap layer 170c may be substantially the same as the vertical thickness d1 of the first conductive cap layer 170v described with reference to FIG. 4A.

The second conductive cap layer 170c may include a conductive material, and may include, for example, a metal nitride such as titanium nitride (TiN), tantalum nitride (TaN), or tungsten nitride (WN), a metallic material such as aluminum (Al), tungsten (W), or molybdenum (Mo), or a semiconductor material such as doped polysilicon. The first conductive cap layer 150c and the second conductive cap layer 170c may include the same conductive material. In one or more embodiments, the second conductive cap layer 170c may include molybdenum (Mo), but the present disclosure is not limited thereto.

The second contact via 170v may have a step portion between the second conductive cap layer 170c and the second conductive cap layer 170c. More specifically, the side surface of the second contact via 170v and the side surface of the second conductive cap layer 170c may have a step portion at the junction of said side surfaces. Accordingly, at least a portion of an upper surface of the second conductive cap layer 170c may be in contact with the second intermediate interlayer insulating layer 184. Put another way, at least a portion of the second intermediate interlayer insulating layer 184 may overlap the upper surface of the second conductive cap layer 170c.

The etch stop layer 185 may be disposed on the intermediate interlayer insulating layers 180. For example, the etch stop layer 185 may be arranged to have substantially the same level on the second intermediate interlayer insulating layer 184. The etch stop layer 185 may function as an etch stop layer in an etch process of forming the interconnection lines M1. The etch stop layer 185 may include a high-κ material, and may include, for example, at least one of aluminum oxide (Al₂O₃), aluminum nitride (AlN), hafnium oxide (HfO₂), zirconium oxide (ZrO₂) and silicon oxycarbide (SiOC), and combinations thereof. According to one or more embodiments, the etch stop layer 185 may be formed of multiple layers.

The upper interlayer insulating layer 190 may be disposed on the etch stop layer 185. The upper interlayer insulating layer 190 may be formed of silicon oxide or a low-κ material. The upper interlayer insulating layer 190 may include, for example, at least one of SiO, SiN, SiCN, SiOC, SiON, and SiOCN. According to one or more embodiments, the upper interlayer insulating layer 190 may be formed of a plurality of layers.

The interconnection lines 191 are interconnection lines (FIG. 2) disposed in upper portions of the active regions ACT and the gate structure 140, and the interconnection lines 191 may be disposed to correspond to the interconnection lines M1 of FIG. 1.

Referring to FIG. 1, the interconnection lines M1 may include a first power transmission line M1_VDD, a second power transmission line M1_VSS, and signal transmission lines M1_S. The first power transmission line M1_VDD and the second power transmission line M1_VSS may be power transmission lines configured to respectively supply different power voltages VDD and VSS to the semiconductor component, and may be electrically connected to the source/drain regions on the active regions ACT. The signal transmission lines M1_S may be signal transmission lines configured to supply signals to the semiconductor component, and may be electrically connected to a gate electrode GL_G. Referring to FIG. 2, the interconnection lines 193 and 195 may have a configuration corresponding to the signal transmission lines M1_S, and the interconnection line 197 may have a configuration corresponding to the first power transmission line M1_VDD or the second power transmission line M1_VSS.

According to the present disclosure, the first conductive cap layer 150c having a horizontal width smaller than a horizontal width of the first contact via 150v may be disposed on the first contact via 150v of the gate contact structure 150, thereby minimizing or preventing a short-circuit phenomenon between the gate contact structure 150 and the interconnection line 195.

Similarly, the second conductive cap layer 170c having a horizontal width smaller than a horizontal width of the second contact via 170v may be disposed on the second contact via 170v of the source/drain contact structure 160, thereby minimizing or preventing a short-circuit phenomenon between the source/drain contact structure 160 and the interconnection line 195.

According to the present disclosure, lower surfaces of each of the interconnection lines 191 may be on substantially the same level as each other. Specifically, the interconnection line 193 in contact with the gate contact structure 150 may have a lower surface that is substantially on the same level in the first direction (e.g., X-direction) as a lower surface of the interconnection line 197 in contact with the source/drain contact structure 160. Accordingly, it may be possible to reduce contact defects that may occur between the interconnection lines 191 and the contact structures 150 and 170.

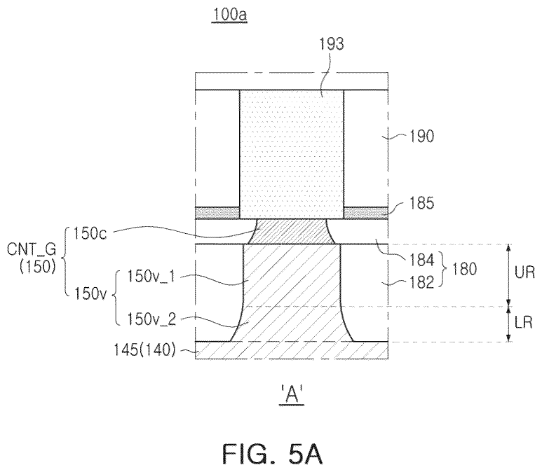

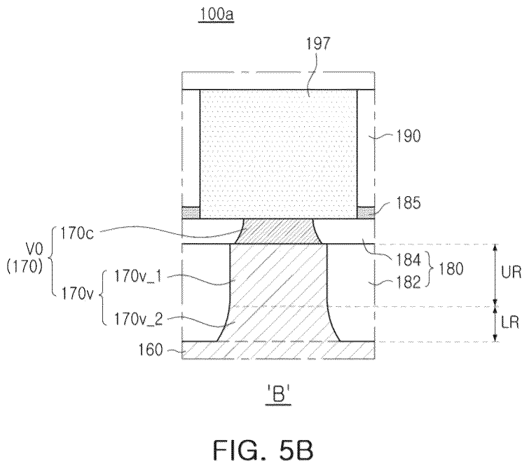

FIGS. 5A and 5B are partially enlarged views of a semiconductor device according to one or more embodiments. FIG. 5A is a partially enlarged view of region “A” in FIG. 2, and FIG. 5b is a partially enlarged view of region “B” of FIG. 2.

Referring to FIGS. 5A and 5B, a semiconductor device 100a may be identical to or similar to that described with reference to FIGS. 1 to 4B, except that the contact vias 150v and 170v have side surfaces including flat portions and curved portions, depending on the region.

Referring to FIG. 5A, a first contact via 150v of a gate contact structure 150 may be defined as having a lower region LR and an upper region UR. The first contact via 150v may include a first contact via portion 150v_1 in the upper region UR and a second contact via portion 150v_2 in the lower region LR.

The first contact via portion 150v_1 may be defined as a portion having a side surface perpendicular to an upper surface of the gate structure 140 (or the gate electrode layer 145). More specifically, a side surface of the first contact via portion 150v_1 may be perpendicular to the upper surface of the substrate 101 (see also FIG. 2). Accordingly, a horizontal width of the first contact via portion 150v_1 may be substantially at heights corresponding to the perpendicular portion.

The second contact via portion 150v_2 may be defined as a portion disposed between the first contact via portion 150v_1 and the gate structure 140 and having a curved side surface. A side surface of the second contact via portion 150v_2 may have a shape similar to or identical to a shape of a side surface of the first contact via 150v described with reference to FIG. 4A.

For example, a horizontal width of the second contact via portion 150v_2 may increase as the second contact via portion 150v_2 approaches the upper surface of the gate structure 140. Put another way, the side surface of the second contact via portion 150v_2 may have a curved shape so that a horizontal distance between the side surface of the second contact via portion 150v_2 and a central axis of the first contact via 150v increases toward the upper surface of the gate structure 140.

Similarly, referring to FIG. 5B, a second contact via 170v of a via structure 170 may be defined as having a lower region LR and an upper region UR. The second contact via 170v may include a first contact via portion 170v_1 in the upper region UR and a second contact via portion 170v_2 in the lower region LR.

The first contact via portion 170v_1 may be defined as a portion having a side surface perpendicular to the upper surface of the source/drain contact structure 160. More specifically, a side surface of the first contact via portion 170v_1 may be perpendicular to the upper surface of the substrate 101 (see also FIG. 2). Accordingly, a horizontal width of the first contact via portion 170v_1 may be substantially the same at heights corresponding to the perpendicular portion.

The second contact via portion 170v_2 may be defined as a portion disposed between the first contact via portion 170v_1 and the source/drain contact structure 160 and having a curved side surface. A side surface of the second contact via portion 170v_2 may have a shape identical to or similar to a shape of the side surface of the second contact via 170v described with reference to FIG. 4B.

For example, a horizontal width of the second contact via portion 170v_2 may increase as the second contact via portion 170v_2 approaches the upper surface of the gate structure 140. Put another way, the side surface of the second contact via portion 170v_2 may have a curved shape so that a horizontal distance between the side surface of the second contact via portion 170v_2 and a central axis of the second contact via 170v increases toward the upper surface of the gate structure 140.

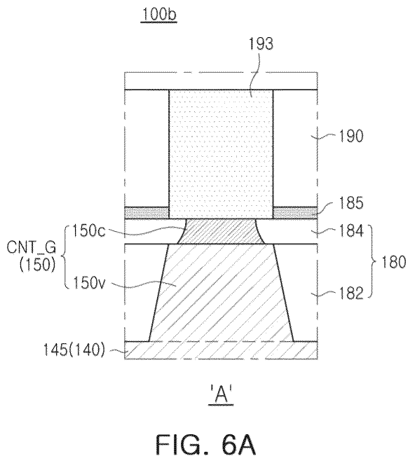

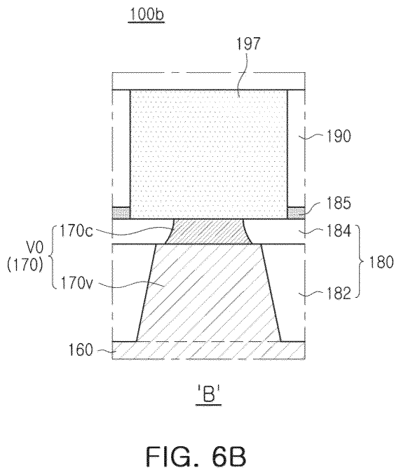

FIGS. 6A and 6B are partially enlarged views of a semiconductor device according to one or more embodiments. FIG. 6A is a partially enlarged view of region “A” of FIG. 2, and FIG. 6B is a partially enlarged view of region “B” in FIG. 2.

Referring to FIGS. 6A and 6B, a semiconductor device 100b may be identical to or similar to that described with reference to FIGS. 1 to 5B, except that the contact vias 150v and 170v have side surfaces that are substantially coplanar.

Referring to FIG. 6A, an inclination of one side surface of a first contact via 150v of a gate contact structure 150 may be constant based on the upper surface of the gate structure 140 (or the gate electrode layer 145). Put another way, a horizontal width of the first contact via 150v may increase uniformly toward the lower region.

Similarly, referring to FIG. 6B, an inclination of one side surface of a second contact via 170v of a source/drain contact structure 160 may be constant based on the upper surface of the source/drain contact structure 160. Put another way, a horizontal width of the first contact via 150v may increase uniformly toward the lower region.

Although the first contact via 150v and the second contact via 170v have been described to have the same structure throughout FIGS. 4A and 4B, 5A and 5B, and 6A and 6B, respectively, the present disclosure is not limited thereto. That is, the first contact via 150v and the second contact via 170v may have different structures. For example, the first contact via 150v may have the structure described with reference to FIG. 4A, and the second contact via 170v may have the structure described with reference to FIG. 5B. In summary, the first contact via 150v may have any one of the structures described with reference to FIGS. 4A, 5A and 6A, and the second contact via 170v may have any one of the structures described with reference to FIGS. 4B, 5B and 6B.

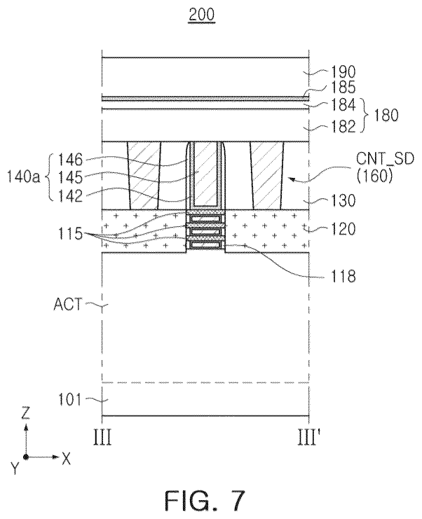

FIG. 7 is a cross-sectional view illustrating a semiconductor device according to one or more embodiments. FIG. 7 illustrates cross-sections taken along cutting line III-III′ of the semiconductor device of FIG. 1.

Referring to FIG. 7, a semiconductor device 200 may further include a plurality of channel layers 115 vertically spaced from each other on the active regions ACT, and internal spacer layers 118 disposed in parallel with the gate electrode layer 145 between the plurality of channel layers 115. The semiconductor device 200 may include transistors having a gate-all-around structure in which the gate structure 140a is disposed between the active fin and the channel layers 115 and between a plurality of nano-sheet-shaped channel layers 115. For example, the semiconductor device 200 may include transistors having a Multi Bridge Channel FET (MBCFET) structure formed by the channel layers 115, the source/drain regions 120, and the gate structures 140a.

The plurality of channel layers 115 may be arranged so that two or more channel layers 115 are spaced apart from each other on the active fin in a direction, perpendicular to the top surface of the active fin, for example, in the Z-direction. The channel layers 115 may be connected to the source/drain regions 120 and may be spaced apart from upper surfaces of the active fins. The channel layers 115 may have a width identical to or similar to a width of the active fin in the Y-direction, and may have a width identical to or similar to a width of the gate structure 140a in the X-direction. However, according to one or more embodiments, the channel layers 115 may have a reduced width so that side surfaces thereof are disposed in a lower portion of the gate structure 140a in the X-direction.

The plurality of channel layers 115 may be formed of a semiconductor material, and may include, for example, at least one of silicon (Si), silicon germanium (SiGe), and germanium (Ge). For example, the channel layers 115 may be formed of the same material as the substrate 101. The number and shape of the channel layers 115 included in one channel structure may be variously changed in one or more embodiments. For example, according to one or more embodiments, a channel layer may be further disposed in a region in which the active fins are in contact with the gate electrode layer 145.

The gate structure 140a may be disposed to extend from upper portions of the active fins and the plurality of channel layers 115 to intersect the active fins and the plurality of channel layers 115. Channel regions of transistors may be formed in the active fins and the plurality of channel layers 115 intersecting the gate structure 140a. In one or more embodiments, the gate dielectric layer 142 may be disposed not only between the active fin and the gate electrode layer 145, but also between the plurality of channel layers 115 and the gate electrode layer 145. The gate electrode layer 145 may be disposed to fill a space between the plurality of channel layers 115 on the upper portions of the active fins and extend from an upper portion of the plurality of channel layers 115. The gate electrode layer 145 may be spaced apart from the plurality of channel layers 115 by the gate dielectric layer 142.

The internal spacer layers 118 may be arranged in parallel with the gate electrode layer 145 between the plurality of channel layers 115. The gate electrode layer 145 may be spaced apart from the source/drain regions 120 by the internal spacer layers 118 and electrically isolated therefrom. The internal spacer layers 118 may have a flat side surface facing the gate electrode layer 145 or may have a rounded shape convex inwardly toward the gate electrode layer 145. The internal spacer layers 118 may be formed of an oxide, a nitride, or an oxynitride, and specifically, may be formed of a low-κ film.

In one or more embodiments, the semiconductor device 200 having the MBCFET structure may be disposed in one region of the semiconductor device described above with reference to FIGS. 1 to 6B. Additionally, in one or more embodiments, the semiconductor device may also include, in at least one region, a vertical field effect transistor (vertical FET) in which an active region extending perpendicularly to the upper surface of the substrate 101 and a gate structure surrounding the active region is disposed.

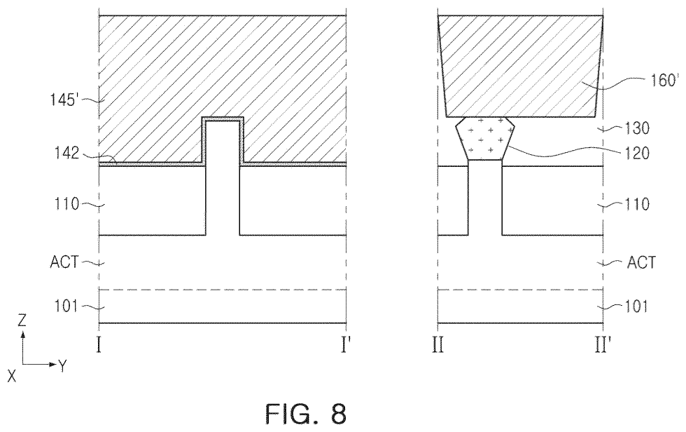

FIGS. 8 to 17 are vertical cross-sectional views illustrating a method of manufacturing a semiconductor device according to one or more embodiments of the present disclosure according to a process order.

FIGS. 8 to 15 may be process diagrams illustrates a middle of line (MOL) process order of a semiconductor device 100 according to one or more embodiments.

Referring to FIG. 8, a substrate 101, a device isolating layer 110 defining an active region ACT on the substrate 101, a gate structure 140 on the active region ACT, a source/drain region 120 formed on at least one side of the gate structure 140 on the active region ACT, a lower interlayer insulating layer 130 covering the gate structure 140 and the source/drain region 120, and a source/drain contact structure 160 on the source/drain region 120 may be formed.

The device isolating layer 110 may be formed by patterning the substrate 101 to form a predetermined trench defining the active fins and then filling the trench with an insulating material. Then, an upper region of the active fin may be allowed to protrude into the substrate 101 by removing a portion of the insulating material.

Then, a dummy gate insulating layer and a dummy gate electrode extending to intersect the active fin may be sequentially stacked, and then, spacers 146 may be formed on both sides of the dummy gate insulating layer and the dummy gate electrode (see the spacer 146 in FIG. 3). Next, portions of the active fins may be selectively removed from both sides of the spacer 146.

Next, referring to FIG. 3 together, the source/drain regions 120 may be formed on the recessed active fins on both sides of the spacer 146. The source/drain region 120 may be formed using, for example, a selective epitaxial growth (SEG) process. The source/drain region 120 may be grown along a crystallographically stable surface during a growth process and may have a pentagonal or hexagonal shape as illustrated. However, the size and shape of the source/drain region 120 are not limited to those illustrated in the drawings.

Then, a lower interlayer insulating layer 130 covering the source/drain region 120 may be formed, and a gate dielectric layer 142 may be formed by removing the dummy gate insulating layer and the dummy gate electrode, and the lower interlayer insulating layer 130 may be recessed to expose a portion of the source/drain region 120.

Then, a first conductive structure 145′ and a second conductive structure 160′ may be formed. The first conductive structure 145′ and the second conductive structure 160 may include a conductive material and, for example, may be formed of molybdenum (Mo).

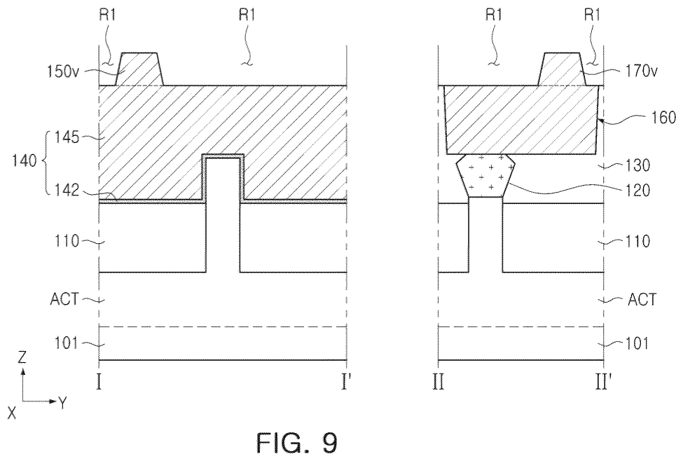

Referring to FIG. 9, the first conductive structure 145′ and the second conductive structure 160′ may be recessed to form first and second contact vias 150v and 170v.

After forming a predetermined mask layer on the first conductive structure 145′, recessed regions R1 defining the gate electrode layer 145 and the first contact via 150v having a shape protruding from an upper surface of the gate electrode layer 145 may be formed using a mask layer.

Similarly, after forming the mask layer on the second conductive structure 160′, recessed regions R1 defining the source/drain contact structure 160 and the second contact via 170v having a shape protruding from an upper surface of the source/drain contact structure 160 may be formed using the mask layer.

The mask layer may be provided simultaneously on the first conductive structure 145′ and the second conductive structure 160′, and the recessed regions R1 defining the first and second contact vias 150v and 170v may also be formed simultaneously.

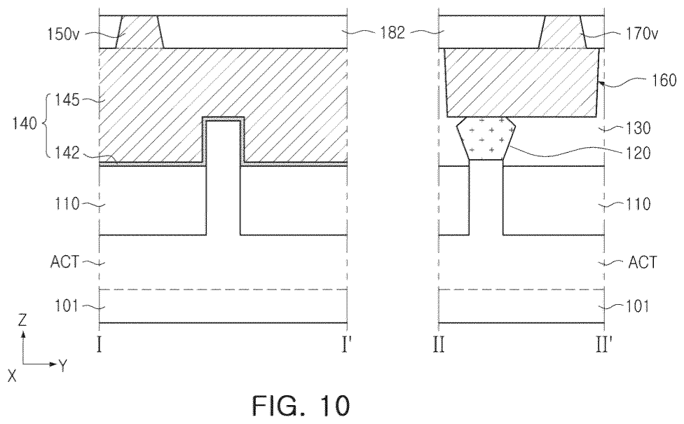

Referring to FIG. 10, a first intermediate interlayer insulating layer 182 may be formed in the recessed regions R1.

An insulating material may be deposited in the recessed regions R1 to cover the gate electrode layer 145, the first contact via 150v, the source/drain contact structure 160, and the second contact via 170v, so that upper surfaces of the first and second contact vias 150v and 170v may be exposed through a Chemical Mechanical Polishing (CMP) process. The insulating material may include an oxide, a nitride, or an oxynitride. For example, the insulating material may include at least one of SiO, SiN, and SiON. In one or more embodiments, the insulating material may include SiN.

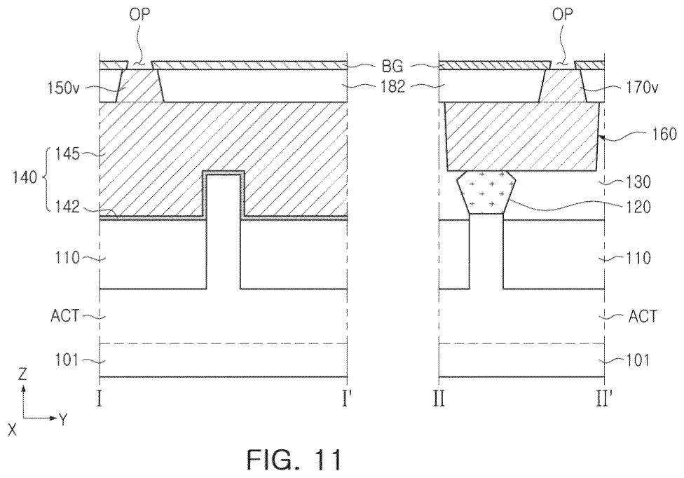

Referring to FIG. 11, an insulating film BG may be formed by selectively depositing an insulating material on the first intermediate interlayer insulating layer 182 and growing the insulating material upwardly. Prior to this, according to one or more embodiments, a passivation layer may first be formed on upper surfaces of the first and second contact vias 150v and 170v. The insulating film BG may be formed by, for example, an area-selective atomic layer deposition (AS-ALD) method, but the present disclosure is not limited thereto. The insulating film BG may be formed of an insulating material different from that of the first intermediate interlayer insulating layer 182.

A portion of the insulating film BG may be formed to overlap the first and second contact vias 150v and 170v. For example, a lower surface of the insulating film BG may be formed to contact the upper surfaces of the first and second contact vias 150v and 170v, and an upper region of the insulating film BG may have an overhang structure (see FIG. 4A).

Accordingly, openings OP may be defined on the first and second contact vias 150v and 170v. At least a portion of the upper surfaces of the first and second contact vias 150v and 170v may be exposed through the openings OP.

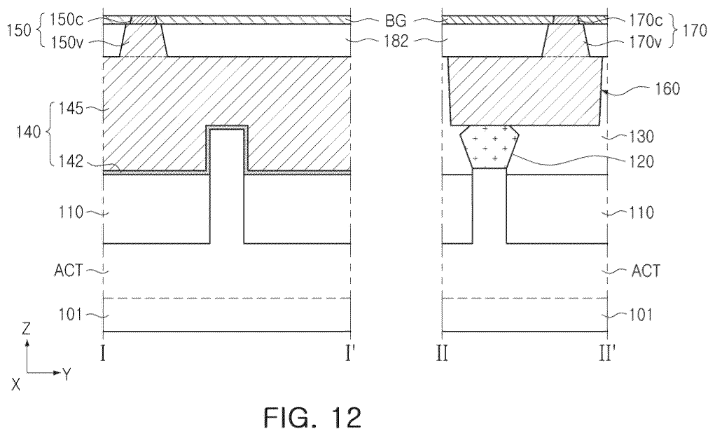

Referring to FIG. 12, first and second conductive cap layers 150c and 170c may be formed by selectively depositing a conductive material in the openings OP.

The first and second conductive cap layers 150c and 170c may be formed by selectively depositing a conductive material on the upper surfaces of the first and second contact vias 150v and 170v exposed by the openings OP. The first and second conductive cap layers 150c and 170c may be formed by, for example, the area-selective atomic layer deposition (AS-ALD) method, but the present disclosure is not limited thereto.

Then, the upper surfaces of the first and second conductive cap layers 150c and 170c may be made to have a flat surface through a Chemical Mechanical Polishing (CMP) process.

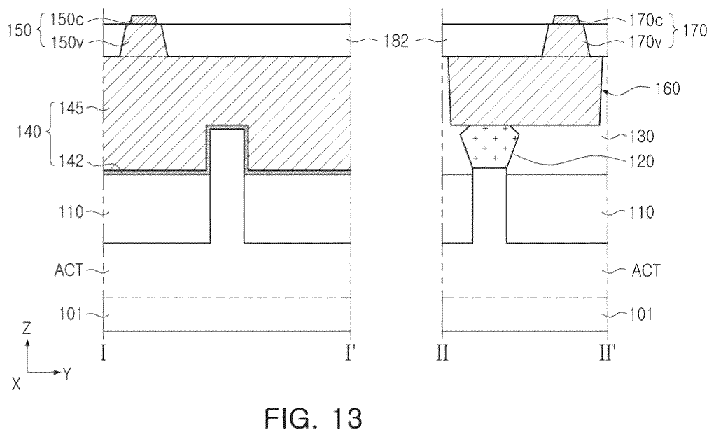

Referring to FIG. 13, the insulating film BG may be selectively removed.

Since the insulating film BG and the first intermediate interlayer insulating layer 182 are formed of different insulating materials, the insulating film BG may be selectively removed due to the difference in etching selectivity.

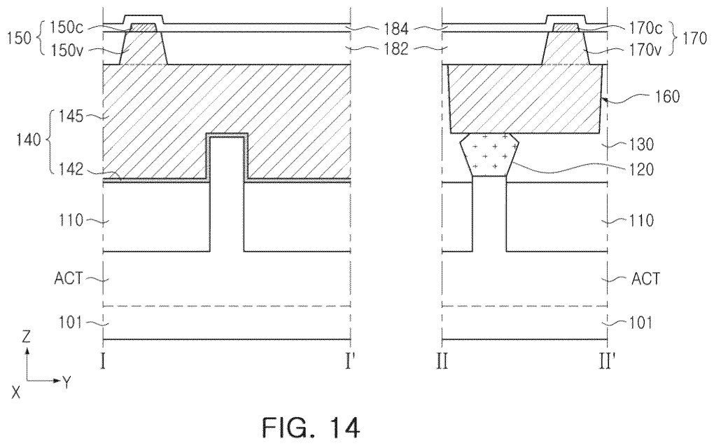

Referring to FIG. 14, a second intermediate interlayer insulating layer 184 covering the surfaces of the first and second conductive cap layers 150c and 170c may be formed on the first intermediate interlayer insulating layer 182.

The second intermediate interlayer insulating layer 184 may be formed conformally by depositing an insulating material on surfaces of the first intermediate interlayer insulating layer 182 and the first and second conductive cap layers 150c and 170c. The insulating material may be formed of an oxide, a nitride, or an oxynitride, and may be formed especially of a low-κ film. The second intermediate interlayer insulating layer 184 may include, for example, at least one of SiO, SiN, SiCN, SiOC, SiON, and SiOCN. In one or more embodiments, the second intermediate interlayer insulating layer 184 may be made of SiN or a low-κ film.

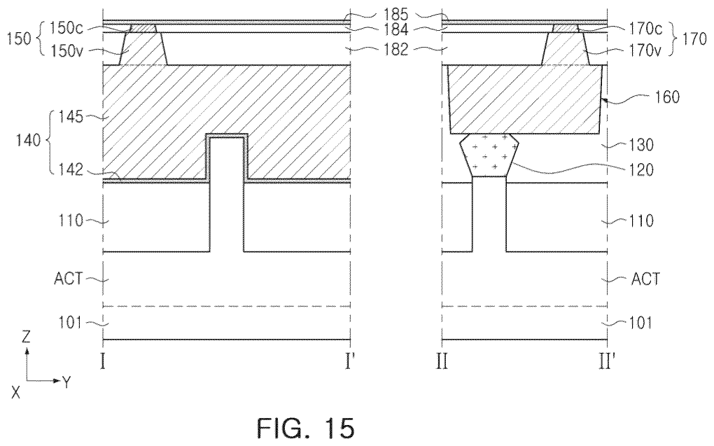

Referring to FIG. 15, an etch stop layer 185 may be formed on the second intermediate interlayer insulating layer 184.

After exposing upper surfaces of the first and second conductive cap layers 150c and 170c through the Chemical Mechanical Polishing (CMP) process, the etch stop layer 185 may be conformally formed on the second intermediate interlayer insulating layer 184 and the first and second conductive cap layers 150c and 170c.

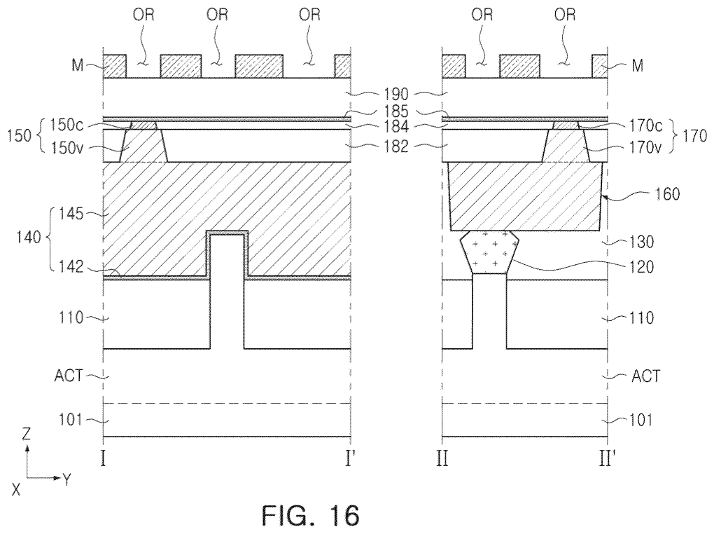

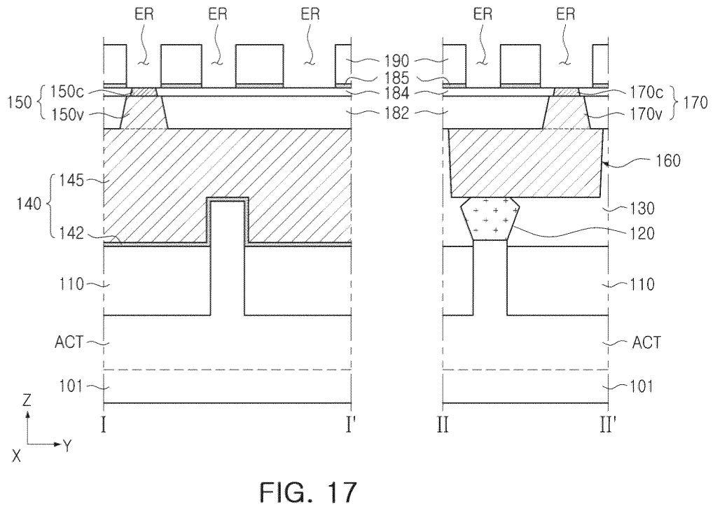

FIGS. 16 and 17 may be process diagrams illustrating a back end of line (BEOL) process order of a semiconductor device 100 according to one or more embodiments. FIG. 16 may be a process diagram following FIG. 15.

Referring to FIG. 16, an upper interlayer insulating layer 190 may be formed on the etch stop layer 185, and a mask layer M having a plurality of open regions OR may be formed on the upper interlayer insulating layer 190.

The upper interlayer insulating layer 190 may be conformally formed on the etch stop layer 185.

The mask layer M may be aligned on the upper interlayer insulating layer 190 so that at least a portion of the open regions OR are disposed on a gate contact structure 150 and a via structure 170.

At least a portion of the upper surface of the upper interlayer insulating layer 190 may be exposed by the open regions OR.

Referring to FIG. 17, the upper interlayer insulating layer 190 may be patterned using the mask layer M.

An etch region ER may be formed by removing the upper interlayer insulating layer 190 exposed by the open regions OR1 and removing the etch stop layer 185 exposed after removing the upper interlayer insulating layer 190.

When referring to FIG. 1, the etch region ER may be formed to have a line-type shape. Then, the etch region ER may be filled with a conductive material to form interconnection lines 191 (see FIG. 2).

Next, an interlayer insulating layer covering the interconnection lines 191 may be additionally formed on the upper interlayer insulating layer 190, and upper vias penetrating through the interlayer insulating layer and connected to the interconnection lines 191 and upper interconnection lines configured to electrically connect the interconnection lines 191 may be formed on the interlayer insulating layer. If necessary, the process of forming the interlayer insulating layer, the upper via, and the upper interconnection lines may be identically repeated.

The present disclosure is not limited to the above-described embodiments and the accompanying drawings but is defined by the appended claims. Those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device comprising:
an active region on a substrate;
a gate structure comprising a gate electrode, wherein the gate structure intersects the active region;
a source/drain region on the active region, wherein the source/drain region is on at least one side of the gate structure;
a first contact structure on the source/drain region and connected to the source/drain region;
a first insulating layer and a second insulating layer sequentially disposed on the gate structure and the first contact structure;
a second contact structure connected to the gate electrode, wherein the second contact structure comprises:
a first contact via in the first insulating layer and protruding vertically from an upper surface of the gate electrode; and
a first conductive cap layer in the second insulating layer and on the first contact via;
a via structure connected to the first contact structure, wherein the via structure comprises:
a second contact via in the first insulating layer and protruding vertically from an upper surface of the first contact structure; and
a second conductive cap layer in the second insulating layer and on the second contact via; and
a plurality of interconnection lines on the second insulating layer, wherein the plurality of interconnection lines are each connected to the second contact structure and the via structure.

2. The semiconductor device of claim 1, wherein a horizontal width of the first conductive cap layer increases in a direction toward the first contact via, and a horizontal width of the second conductive cap layer increases in a direction toward the second contact via.

3. The semiconductor device of claim 1,
wherein a side surface of the first conductive cap layer has a curved shape concave toward a central axis of the first conductive cap layer, and
wherein a horizontal distance between the side surface of the first conductive cap layer and the central axis of the first conductive cap layer increases in a direction toward the first contact via.

4. The semiconductor device of claim 3,
wherein a side surface of the second insulating layer is convex toward the central axis of the first conductive cap layer,
wherein the second insulating layer is in contact with the first conductive cap layer, and
wherein a horizontal distance between the side surface of the second insulating layer and the central axis of the first conductive cap layer decreases in a direction moving away from the first contact via.

5. The semiconductor device of claim 3,
wherein a side surface of the second conductive cap layer has a curved shape concave toward a central axis of the second conductive cap layer, and
wherein a horizontal distance between the side surface of the second conductive cap layer and the central axis of the second conductive cap layer increases in a direction toward the second contact via.

6. The semiconductor device of claim 1,
wherein a side surface of the first contact via and a side surface of the first conductive cap layer form a first surface, the first surface comprising a step portion between the side surface of the first contact via and the side surface of the first conductive cap layer, and
wherein a side surface of the second contact via and a side surface of the second conductive cap layer form a second surface, the second surface comprising a step portion between the side surface of the second contact via and the side surface of the second conductive cap layer.

7. The semiconductor device of claim 6, wherein the second insulating layer overlaps at least a portion of an upper surface of at least one of the first contact via and the second contact via.

8. The semiconductor device of claim 1, wherein a horizontal width of at least one of the first contact via and the second contact via increases in a direction toward the upper surface of the gate electrode or the upper surface of the first contact structure, respectively.

9. The semiconductor device of claim 1,
wherein a side surface of the first contact via has a curved shape concave toward a central axis of the first contact via, and
wherein a horizontal distance between the side surface of the first contact via and the central axis of the first contact via increases in a direction toward the upper surface of the gate electrode.

10. The semiconductor device of claim 9,
wherein a side surface of the second contact via has a curved shape concave toward a central axis of the second contact via, and
wherein a horizontal distance between the side surface of the second contact via and the central axis of the second contact via increases in a direction toward the upper surface of the first contact structure.

11. The semiconductor device of claim 1, further comprising:
a plurality of channel layers spaced apart from each other in a vertical direction on the active region,
wherein the vertical direction is perpendicular to an upper surface of the substrate, and
wherein the gate structure surrounds the plurality of channel layers.

12. The semiconductor device of claim 1, wherein a side surface of at least one of the first contact via and the second contact via comprises:
a first portion perpendicular to an upper surface of the substrate; and
a second portion extending downwardly from the first portion and having a curved shape.

13. The semiconductor device of claim 1, wherein a vertical thickness of at least one of the first conductive cap layer and the second conductive cap layer ranges from 3 nm to 10 nm.

14. The semiconductor device of claim 1, wherein a vertical thickness of at least one of the first contact via and the second contact via ranges from 10 nm to 30 nm.

15. A semiconductor device comprising:
an active region on a substrate;
a gate structure comprising a gate electrode, wherein the gate structure intersects the active region;
a source/drain region on the active region, wherein the source/drain region is on at least one side of the gate structure;
a contact structure on the source/drain region and connected to the source/drain region;
a first insulating layer and a second insulating layer sequentially disposed on the gate structure and the contact structure;
a via structure connected to the contact structure, the via structure comprising a contact via in the first insulating layer and vertically protruding from an upper surface of the contact structure, and a conductive cap layer in the second insulating layer and on the contact via; and
an etch stop layer on the second insulating layer and the via structure,
wherein a maximum horizontal width of the conductive cap layer is smaller than a maximum horizontal width of the contact via, and
a side surface of the conductive cap layer and a side surface of the contact via form a first surface comprising a step portion between the side surface of the conductive cap layer and the side surface of the contact via.

16. The semiconductor device of claim 15,
wherein a horizontal width of the contact structure decreases in a direction toward an upper surface of the substrate, and
wherein a horizontal width of the contact via decreases in a direction moving away from the upper surface of the substrate.

17. The semiconductor device of claim 15, wherein the etch stop layer is on substantially the same level on the second insulating layer.

18. The semiconductor device of claim 15, further comprising:
an interconnection line on the second insulating layer,
wherein the interconnection line is connected to the via structure and penetrates the etch stop layer, and
wherein a lower surface of the interconnection line is on substantially the same level as an upper surface of the substrate.

19. A semiconductor device comprising:
an active region extending on a substrate in a first direction;
a gate structure comprising a gate electrode, wherein the gate structure intersects the active region and extends in a second direction;
a source/drain region on the active region, wherein the source/drain region is on at least one side of the gate structure;
a first contact structure on the source/drain region and connected to the source/drain region, wherein an upper surface of the first contact structure and an upper surface of the gate structure are on the same level;
a second contact structure connected to the gate electrode, wherein the second contact structure comprises a first contact via on the gate electrode and a first conductive cap layer on the first contact via, and wherein the first contact via has a first thickness and the first conductive cap layer has a second thickness;
a via structure connected to the first contact structure, wherein the via structure comprises a second contact via on the first contact structure and a second conductive cap layer on the second contact via, and wherein the second contact via has a thickness equal to the first thickness and the second conductive cap layer has a thickness equal to the second thickness;
an insulating layer surrounding a side surface of the second contact structure and a side surface of the via structure and the first contact structure; and
a plurality of interconnection lines on the insulating layer, wherein the plurality of interconnection lines are each connected to the second contact structure and the via structure.

20. The semiconductor device of claim 19, wherein the insulating layer comprises:
a first insulating layer surrounding side surfaces of the first and the second contact vias and the first contact structure; and
a second insulating layer surrounding side surfaces of the first and the second conductive cap layers.
